(19) United States
(12) Patent Application Publication
(10) Pub. No.: US 2026/0098881 A1
(43) Pub. Date: Apr. 9, 2026

(54) DETECTING AEROSPACE PROBE HEATER DEGRADATION

(71) Applicant: Rosemount Aerospace Inc., Burnsville, MN (US)

(72) Inventors: Daniel P. Higgins, Lakeville, MN (US); Kenneth J. Freeman, Eagan, MN (US); Scott Braun, Elko New Market, MN (US); Brian W. Hawley, New Market, MN (US); Greg A. Seidel, Lakeville, MN (US)

(21) Appl. No.: 18/905,726

(22) Filed: Oct. 3, 2024

(51) Int. Cl. G01R 19/165; B64D 15/12; G01M 99/00

(52) U.S. Cl. CPC G01R 19/16576; B64D 15/12; G01M 99/002

(57) ABSTRACT

An aerospace probe assembly and method for detecting a degraded operating condition of a probe heater. The method includes detecting at least one of a current differential in the probe heater and a temperature differential in the probe casing indicating a degraded operating condition of the probe heater. In embodiments, a controller implemented as a comparator circuit is configured to compare at least one measurement differential to at least one predefined threshold and generate at least one alarm when the at least one predefined threshold is exceeded to inform the flight crew regarding a degraded operating condition of the heater probe resulting in a potentially unsafe flight condition.

### TECHNICAL FIELD AND BACKGROUND

The present disclosure relates generally to aerospace probes, and more particularly, to detecting a degraded operating condition of an aerospace probe heater.

Aerospace probes such as pitot or pitot-static tubes, fuselage mounted total air temperature sensors, and angle of attack measuring devices typically include an internal probe heater for deicing the probe during aircraft icing conditions. Considering the critical importance of these probes, the aircraft industry has expressed a need for the ability to detect a probe heater that is not functioning normally with respect to its ability to sufficiently deice the probe, which could potentially cause an erroneous and misleading output that could impact flight safety (see e.g., European Aviation Safety Agency (EASA) CS 25.1326 (b)(2)).

A common failure mechanism for a degraded probe heater implemented as a resistive heating element is low insulation resistance (IR) or an electrical short (very low impedance or resistance) from the embedded heating element to the probe case or external probe structure. Normally the resistive heating element is insulated via a dielectric material from the probe case per the construction of the probe and probe heater. A breakdown of the insulating dielectric material can cause a low impedance path from the resistive heating element to the probe case. If that path has a low resistance value, the electrical current needed to heat the resistive heating element downstream of the short will be diverted away from the resistive heating element to the probe case. The location of the low impedance short in relation to the length of the resistive heating element will determine if the probe heater can sufficiently deice the probe under aircraft icing conditions.

Traditional solutions for detecting probe heater failure include heater bus circuit breaker tripping resulting from excessive current drawn from the voltage source during the low impedance short, and current detection schemes that detect the complete absence of return current. The disadvantage of these traditional solutions is their inability to detect a low impedance path that does not satisfy their detection criteria. Such a non-detectable condition would be considered a latent failure mechanism as the flight crew would not be alerted to the degraded probe heater potentially resulting in an unsafe flight condition.

Therefore, what is needed are improved solutions for detecting a degraded operating condition of an aerospace probe heater.

### BRIEF SUMMARY

According to one aspect, the inventive concepts according to the present disclosure are directed to a method for detecting a probe heater operating in a degraded condition. In embodiments, the method includes obtaining, by an incoming current sensor coupled to a high potential side of a resistive probe heater, a measurement of incoming electrical current, obtaining, by an outgoing current sensor coupled to a low potential side of the resistive probe heater, a measurement of outgoing electrical current, determining, by a controller including processing circuitry, a difference in electrical current between the measurement of outgoing current and the measurement of incoming current, comparing, by the controller, the difference in electrical current to a predefined threshold, and generating an alarm, by the controller, when the difference in electrical current exceeds the predefined threshold.

In some embodiments, the resistive probe heater may be powered by a direct current (DC) power source, the incoming current sensor and the outgoing current sensor may be matched resistors, the predefined threshold may be a voltage threshold, and the controller may be configured determine a voltage differential between the matched resistors and generate the alarm when the voltage differential exceeds the voltage threshold.

In some embodiments, the controller may be implemented as a voltage comparator circuit having a fault output configured to change from a high voltage state to a low voltage state when the voltage differential exceeds the voltage threshold, the high voltage state may correspond to normal resistive probe heater operation, and the low voltage state may correspond to degraded resistive probe heater operation.

In some embodiments, the resistive probe heater may be powered by an alternating current (AC) power source, the incoming current sensor and the outgoing current sensor may be implemented as at least one current transformer configured to convert the incoming current to incoming voltage and the outgoing current to outgoing voltage, the predefined threshold may be a voltage threshold, and the controller may be configured to determine a voltage differential between the incoming voltage and the outgoing voltage and generate the alarm when the voltage differential exceeds the voltage threshold.

In some embodiments, the controller may be implemented as a voltage comparator circuit having a fault output configured to change from a high voltage state to a low voltage state when the voltage differential exceeds the voltage threshold, the high voltage state may correspond to normal resistive probe heater operation, and the low voltage state may correspond to degraded resistive probe heater operation.

In some embodiments, the probe heater is disposed in an aerospace probe that may include a strut and a head positioned atop the strut, the aerospace probe may include a first side and a second side symmetrical about a vertical plane of symmetry, and the resistive probe heater may be symmetrical about the vertical plane of symmetry to provide symmetric heat distribution in the first and second sides.

In some embodiments, the method may further include obtaining, by a first temperature sensor disposed in a first side of the aerospace probe, a first temperature measurement, obtaining, by a second temperature sensor disposed in a second side of the aerospace probe, a second temperature measurement, determining, by the controller, a difference in temperature between the first temperature measurement and the second temperature measurement, comparing, by the controller, the difference in temperature to a further predefined threshold, and generating a further alarm, by the controller, when the difference in temperature exceeds the predefined threshold.

In some embodiments, the first temperature sensor may be a first thermocouple device, resistance temperature device (RTD), thermistor, etc., configured to output a first voltage, the second temperature sensor may be a second thermocouple device configured to output a second voltage, the predefined threshold may be a voltage threshold, and the controller may be implemented as a differential voltage circuit configured to determine a differential voltage between the first and second voltages and generate the further alarm when the differential voltage exceeds the voltage threshold.

In some embodiments, the controller may be configured to generate the alarm and the further alarm separately or collaboratively, and the controller may be configured to output the alarm and the further alarm to an aircraft system configured to convey situational information to an aircraft flight crew.

According to another aspect, the inventive concepts according to the present disclosure are directed to a method for detecting a degraded operating condition of a probe heater disposed in an aerospace probe. In embodiments, the method includes obtaining, by a first temperature sensor disposed in a first side of the aerospace probe, a first temperature measurement, obtaining, by a second temperature sensor disposed in a second side of the aerospace probe, a second temperature measurement, determining, by a controller including processing circuitry, a difference in temperature between the first temperature measurement and the second temperature measurement, comparing, by the controller, the difference in temperature to a predefined threshold, and generating an alarm, by the controller, when the difference in temperature exceeds the predefined threshold.

In some embodiments, the method may further include obtaining, by an incoming current sensor coupled to a high potential side of the probe heater, a measurement of incoming electrical current, obtaining, by an outgoing current sensor coupled to a low potential side of the probe heater, a measurement of outgoing electrical current, determining, by the controller, a difference in electrical current between the measurement of outgoing current and the measurement of incoming current, comparing, by the controller, the difference in electrical current to a further predefined threshold, and generating a further alarm, by the controller, when the difference in electrical current exceeds the further predefined threshold.

In some embodiments, the controller may be configured to generate the alarm and the further alarm separately or collaboratively, and the controller may be configured to output the alarm and the further alarm to an aircraft system configured to convey situational information to an aircraft flight crew.

According to a further aspect, the inventive concepts according to the present disclosure are directed to an aerospace probe assembly including a probe casing, a resistive prove heater disposed in the probe casing, an incoming current sensor coupled to a high potential side of the resistive probe heater, an outgoing current sensor coupled to a low potential side of the resistive probe heater, and a controller including processing circuitry. In embodiments, the controller is configured to obtain, from the incoming current sensor, a measurement of incoming electrical current, obtain, from the outgoing current sensor, a measurement of outgoing electrical current, determine a difference between the measurement of outgoing electrical current and the measurement of incoming electrical current, compare the difference in electrical current to a predefined threshold, and generate an alarm when the difference in electrical current exceeds the predefined threshold.

In some embodiments, the controller is further configured to output the alarm to an aircraft system configured to convey the degraded operating condition of the probe heater to an aircraft flight crew.

In some embodiments, the probe casing includes a first side and a second side that are continuously formed and symmetrical about a vertical plane of symmetry. In some embodiments, the aerospace probe assembly further includes a first temperature sensor disposed in the first side of the aerospace probe and communicatively coupled to the controller, and a second temperature sensor disposed in a second side of the aerospace probe and communicatively coupled to the controller. In some embodiments, the controller is further configured to obtain from the first temperature sensor a first temperature measurement, obtain from the second temperature sensor a second temperature measurement, determine a difference in temperature between the first temperature measurement and the second temperature measurement, compare the difference in temperature to a further predefined threshold, and generate a further alarm when the difference in temperature exceeds the further predefined threshold.

In some embodiments, the controller may be further configured to output the further alarm to the aircraft system separately from or collaboratively with the output of the alarm to the aircraft system.

### BRIEF DESCRIPTION OF THE DRAWINGS

Implementations of the inventive concepts disclosed herein may be better understood when consideration is given to the following detailed description thereof. Such description refers to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1 is a schematic diagram illustrating the flow of electrical current in a probe heater operating in a normal condition, in accordance with example embodiments of this disclosure;

FIG. 2 is a schematic diagram illustrating the flow of electrical current in a probe heater operating in a degraded condition, in accordance with example embodiments of this disclosure;

FIG. 3 is a schematic diagram illustrating a comparator circuit of a probe heater powered by a DC power source, in accordance with example embodiments of this disclosure;

FIG. 4 is a schematic diagram illustrating a comparator circuit of a probe heater powered by an AC power source, in accordance with example embodiments of this disclosure;

FIG. 5 is a schematic diagram illustrating the probe heater operating in a normal condition and further including temperature sensors, in accordance with example embodiments of this disclosure;

FIG. 6 is a schematic diagram illustrating the probe heater operating in a degraded condition and further including the temperature sensors, in accordance with example embodiments of this disclosure;

FIG. 7 is a schematic diagram illustrating a comparator circuit for determining a temperature differential, in accordance with example embodiments of this disclosure;

FIGS. 8A and 8B are respective front and side elevation views of an aerospace probe, in accordance with example embodiments of this disclosure; and

FIG. 9 is a flow diagram illustrating methodology for detecting a probe heater operating in a degraded condition.

### DETAILED DESCRIPTION

Before explaining at least one embodiment of the inventive concepts disclosed herein in detail, it is to be understood that the inventive concepts are not limited in their application to the details of construction and the arrangement of the components or steps or methodologies set forth in the following description or illustrated in the drawings. In the following detailed description of embodiments of the instant inventive concepts, numerous specific details are set forth in order to provide a more thorough understanding of the inventive concepts. However, it will be apparent to one of ordinary skill in the art having the benefit of the instant disclosure that the inventive concepts disclosed herein may be practiced without these specific details. In other instances, well-known features may not be described in detail to avoid unnecessarily complicating the instant disclosure. The inventive concepts disclosed herein are capable of other embodiments or of being practiced or carried out in various ways. Also, it is to be understood that the phraseology and terminology employed herein is for the purpose of description and should not be regarded as limiting.

As used herein, a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only, and should not be construed to limit the inventive concepts disclosed herein in any way unless expressly stated to the contrary.

Further, unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present).

In addition, use of the “a” or “an” are employed to describe elements and components of embodiments of the instant inventive concepts. This is done merely for convenience and to give a general sense of the inventive concepts, and “a” and “an” are intended to include one or at least one and the singular also includes the plural unless it is obvious that it is meant otherwise.

Finally, as used herein any reference to “one embodiment” or “some embodiments” means that a particular element, feature, structure, or characteristic described in connection with the embodiment is included in at least one embodiment of the inventive concepts disclosed herein. The appearances of the phrase “in some embodiments” in various places in the specification are not necessarily all referring to the same embodiment, and embodiments of the inventive concepts disclosed may include one or more of the features expressly described or inherently present herein, or any combination of sub-combination of two or more such features, along with any other features which may not necessarily be expressly described or inherently present in the instant disclosure.

Broadly, embodiments of the inventive concepts disclosed herein are directed to aerospace probe assemblies and methodologies for detecting a probe heater operating in a degraded condition. As used herein, the term “normal” with respect to the operation or operating condition of the probe heater refers to a suitable, correct, adequate, or non-degraded operating condition, whereas the term “degraded” with respect to the operation or operating condition of the probe heater refers to an unsuitable, incorrect, inadequate, or abnormal operating condition. In that regard, a prober heater operating in a normal operating condition is capable of adequately deicing an aerospace probe as required, whereas a probe heater operating in a degraded operating condition may be incapable of adequately deicing an aerospace probe as required. Deicing may also include anti-icing performance.

In use, the assemblies and methodologies according to the present disclosure perform to monitor and determine, in real time, the operating state of a probe heater. From the determined operating state of the probe heater, situational information can be gained and conveyed in terms of probe heater performance, estimates of the remaining life of a probe heater, predictions about probe heater failure, etc. Whereas the probe heater performance information obtained according to traditional methods pertains only to outright probe heater failure, the information obtained according to the present disclosure is informative about degraded performance that may result in a potentially unsafe flight condition. Thus, the information obtained may be used to determine the need for servicing or component replacement prior to a complete failure condition of the probe heater. Thus, the present disclosure provides both diagnostic and prognostic methodologies for probe heater and aerospace probe performance.

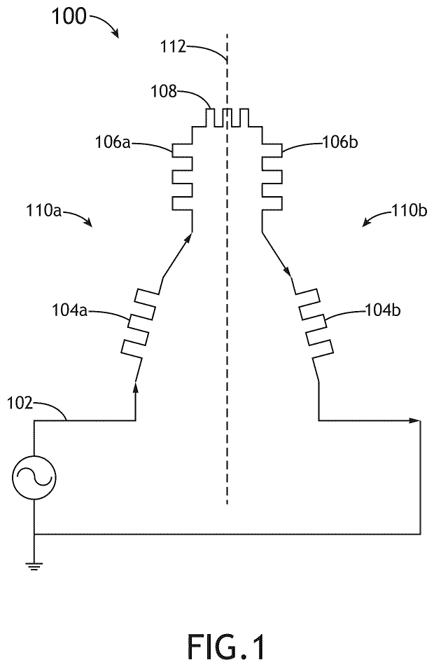

FIG. 1 illustrates a non-limiting example of a configuration of a probe heater 100 implemented as a resistive heating element 102 (e.g., wire). The probe heater 100 shown generally assumes the shape of an aerospace probe including a head mounted atop a strut configured to be attached to an airframe. As shown, the resistive heating element 102 forms, in sequence, a first or ‘left’ side strut heating section 104a, a first or ‘left’ side head heating section 106a, a top heating section 108, a second or ‘right’ side strut heating section 104b, and a second or ‘right’ side head heating section 106b. Other heating section configurations and heater shapes may be practiced depending on the aerospace probe dimensions and configuration.

As shown, the resistive heating element 102 is continuous and forms a first side 110a including in sequence the first or ‘left’ side strut heating section 104a, the first or ‘left’ side head heating section 106a, and a portion of the top heating section 108, and a second side 110b including in sequence a portion of the top heating section 108, the second or ‘right’ side head heating section 106b, and the second or ‘right’ side strut heating section 104b. In embodiments, the first side 110a corresponds to a high potential side of the probe heater 100 and the second side 110b corresponds to a low potential side of the probe heater 100. In embodiments, the first and second sides 110a, 110b of the resistive heating element 102 are symmetrical about a vertical plane of symmetry 112.

The direction of electrical current (also referred to herein as “current”) flow through the resistive heating element 102, from the high potential side to the low potential side, is indicated by the directional arrows. FIG. 1 illustrates a normal operating condition of the probe heater 100 in which the incoming current into the probe heater 100 is the same, or substantially the same, as the outgoing current out of the probe heater 100. In embodiments, the normal operating condition corresponds to a condition in which the supplied current follows the entire path of the resistive heating element 102 to ground and is not diverted elsewhere as a result of the development of a short circuit or other low impedance path, for instance through the probe case.

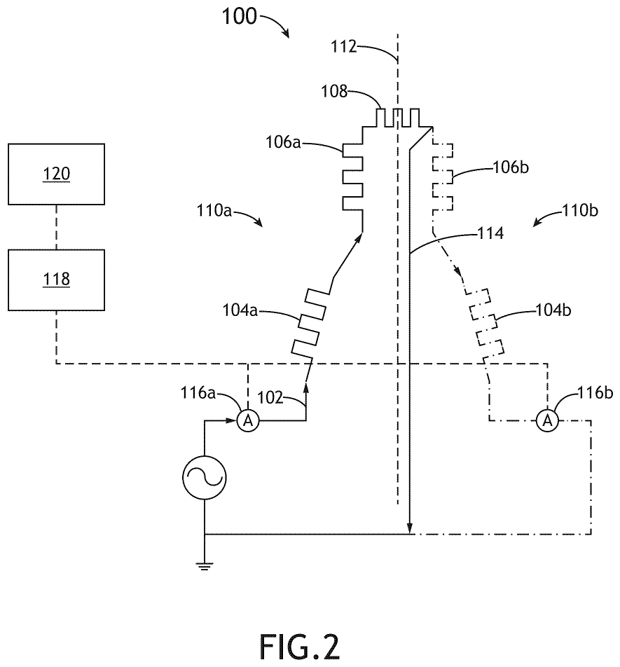

FIG. 2 illustrates a degraded operating condition of the probe heater 100. As shown, a short circuit 114 located downstream of the top heating section 108 causes the current to bypass the downstream heating sections (e.g., second or ‘right’ side head heating section 106 and the second or ‘right’ side strut heating section 104b) and flow via a low impedance path to ground through the probe case. As a result of the short circuit 114, the second side 110b is not supplied the current needed to heat the respective side to prevent icing.

To detect the degraded operating performance, the probe heater 110 includes an incoming current sensor 116a coupled to the high potential side 110a of the resistive heating element 102, and an outgoing current sensor 116b coupled to the low potential side 110b of the resistive heating element 102. The exact physical locations of the current sensors 116a, 116b may vary. As shown, the current sensors 116a, 116b are respectively located proximal to the entry location of the resistive heating element 102 into the probe and exit location of the resistive heating element 104 out of the probe.

According to a first detection methodology, the incoming current sensor 116a coupled to the high potential side 110a is configured to obtain a measurement of incoming current, and the outgoing current sensor 116b coupled to the low potential side 110b is configured to obtain a measurement of outgoing current. When the probe heater 100 is operating in the normal condition, the incoming current measurement and the outgoing current measurement should be equal or substantially equal.

In embodiments, the incoming and outgoing current sensors 116a, 116b are coupled to a controller 118 configured to receive the obtained current measurements, determine a difference in electrical current between the measurement of outgoing current and the measurement of incoming current, and compare the difference in electrical current to a predefined threshold. The predefined threshold is set to identify a difference between the incoming current and the outgoing current sufficient to indicate a degraded operating condition. When the difference in electrical current exceeds the predefined threshold (e.g., a predefined amount determined to affect heater performance to an unacceptable level), the controller 118 is further configured to generate an alarm. In some embodiments, the alarm is output to an aircraft system 120 (e.g., existing or dedicated to the purpose of monitoring probe heater performance) configured to convey situational information to the aircraft flight crew. The alarm may include at least one of a visual alarm, an audible alarm, numerical data, etc. The alarm may be further output to a ground-based monitoring system.

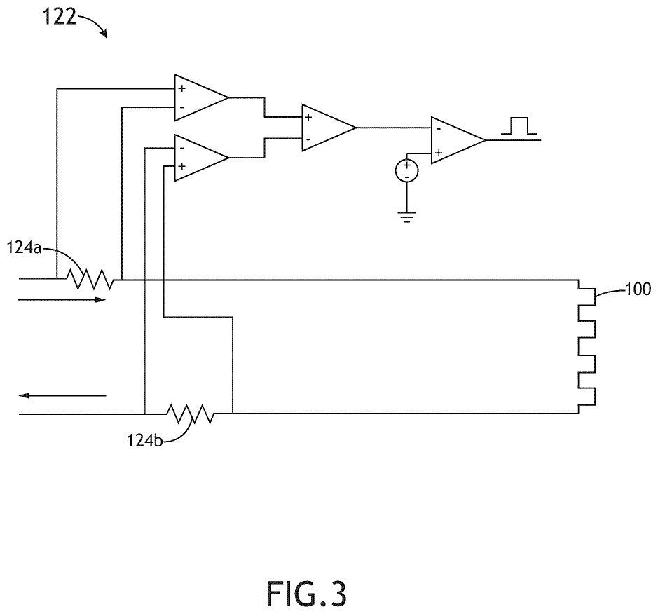

FIG. 3 illustrates a differential voltage circuit 122 for measuring and comparing the incoming and outgoing currents for a DC powered probe heater 100. As shown, the incoming and outgoing current is measured as a voltage drop across respective incoming and outgoing resistors 124a, 124b (e.g., Rᵢₙ and Rₒᵤₜ). The resistors 124a, 124b may be matched resistors having the same low resistance value. According to the method, the controller 118 obtains measurements of voltage drops across the resistors 124a, 124b, compares the obtained measurements to determine a voltage differential, and compares the voltage differential to a predefined threshold voltage.

During normal operation, the current flow through the resistors 124a, 124b will be equal, or substantially equal, and the voltage drop across both resistors 124a, 124b will be equal resulting in 0 (zero) volt output from the differential voltage circuit 122. If a low impedance path develops from the probe heater 100 to the probe case, for example as shown in FIG. 2, the current flow through the outgoing resistor 124b is decreased, resulting in less voltage drop across the outgoing resistor 124b. Any voltage difference will be present at the differential voltage output and then compared against a voltage threshold. If the voltage difference across the resistors 124a, 124b exceeds the voltage threshold, then the fault output of the comparator circuit changes from a high voltage state to a low voltage state. In embodiments, a “HI” at the fault output may indicate normal heater operation, whereas a “LO” at the fault output may indicate degraded heater operation.

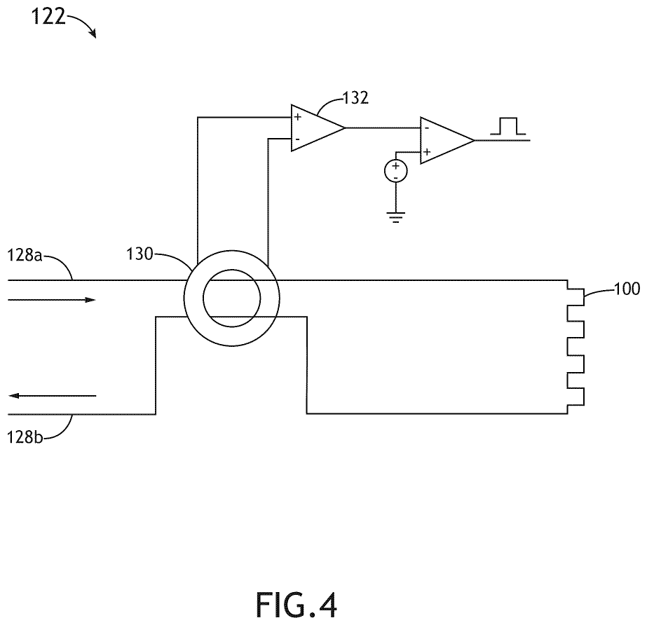

FIG. 4 illustrates a differential voltage circuit 126 for measuring and comparing the incoming and outgoing currents for an AC powered probe heater 100. As shown, the incoming and outgoing current conductors 128a, 128b are passed through a current transformer 130. Differences in the incoming and outgoing currents are converted to a voltage at a current to voltage converter 132 and are compared against a predetermined voltage threshold.

During normal probe heater operation, the incoming and outgoing currents are equal and the currents as seen by the current transformer 130 cancel each other out resulting in a net 0 (zero) output from the current transformer 130 and consequently a zero voltage from the current to voltage converter 132. If a low impedance path develops from the probe heater to probe case, for example as shown in FIG. 2, the outgoing current is decreased resulting in an imbalance of current in the current transformer 130. This imbalance generates a non-zero current in the secondary of the current transformer 130 which is then converted into a non-zero voltage at the output of the current to voltage converter 132. This voltage is then compared against a voltage threshold. If the voltage difference in the current to voltage converter 132 exceeds the voltage threshold, then the fault output of the comparator circuit 126 changes from a high voltage state to a low voltage state. In embodiments, a “HI” at the fault output may indicate normal heater operation, whereas a “LO” at the fault output may indicate degraded heater operation.

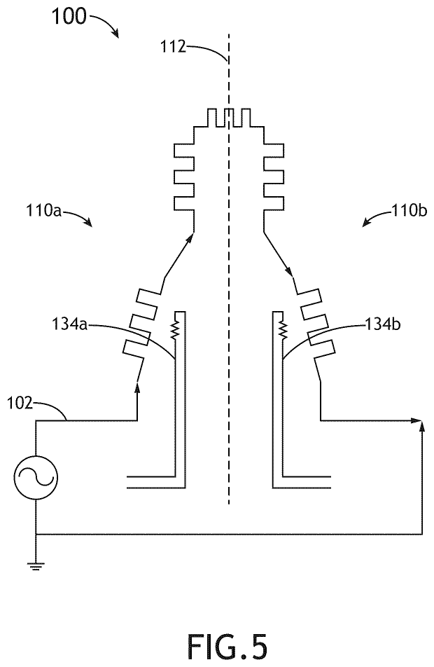

FIG. 5 illustrates the non-limiting example of a configuration of the probe heater 100 implemented as the resistive heating element 102. The resistive heating element 102 is continuous and forms a first side 110a and a second side 110b symmetrical about the vertical plane of symmetry 112. The directional flow of current through the resistive heating element 102, from the high potential side to the low potential side, is indicated by the directional arrows. FIG. 5 illustrates a normal operating condition of the probe heater 100 in which the incoming current into the probe heater 100 is the same as the outgoing current out of the probe heater 100, resulting in an equal, or substantially equal, temperature in the first and second sides.

In this embodiment, the aerospace probe includes at least one first temperature sensor 134a disposed in a first side of the aerospace probe, and at least one second temperature sensor 134b disposed in a second side of the aerospace probe. Each temperature sensor 134a, 134b may be physically located proximal to its respective side 110a, 110b of the resistive heating element 102. Each temperature sensor 134a, 134b is operative to detect a temperature in a region of the aerospace probe. The temperature sensors 134a, 134b may be symmetrically positioned such that, during normal operation, the temperature measurements from the opposing sensors 134a, 134b match.

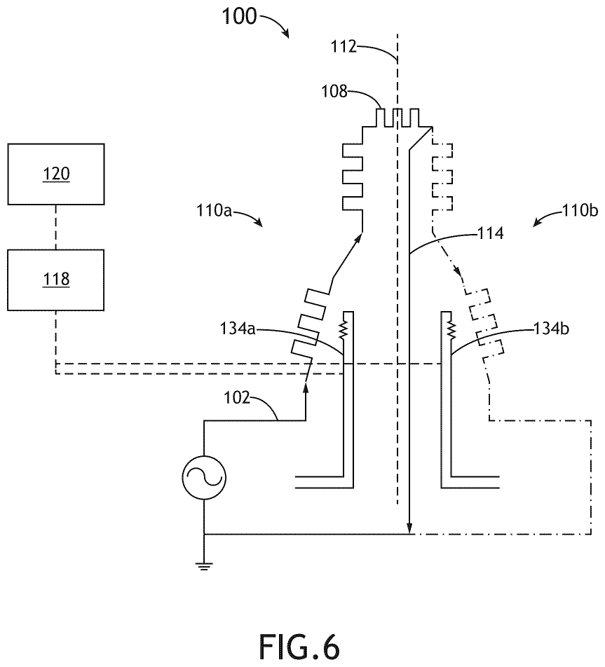

FIG. 6 illustrates a degraded operating condition of the probe heater 100 in which a short circuit 114 located downstream of the top heating section 108 causes the current to bypass the downstream heating sections and flow via a low impedance path to ground through the probe casing. As a result of the short circuit 114, the second side 110b is not supplied sufficient current to perform adequate heating to prevent icing. As a result of the short circuit 114 and current bypass, the temperature in the side of the probe corresponding to the second side 110b of the resistive heating element 102 will be lower than the temperature in the side of the probe corresponding to the first side 110a of the resistive heating element 102.

To ensure that both sides of the probe heater 100 are operating at the same temperature, and to detect degraded heater performance indicative of a short circuit or other failure mechanism, the temperature sensors 134a, 134b are configured to measure the temperature in their physical location. In embodiments, the temperature sensors 134a, 134b are coupled to the controller 118 configured to receive the obtained temperature measurements, determine a difference between the measurements, and compare the difference to a predefined threshold. The predefined threshold is set to identify a difference between the two temperatures sufficient to indicate a degraded heater performance. When the temperature difference exceeds the predefined threshold, the controller 118 is further configured to generate an alarm. In some embodiments, the alarm is output to the aircraft system 120 configured to convey situational information to the aircraft flight crew.

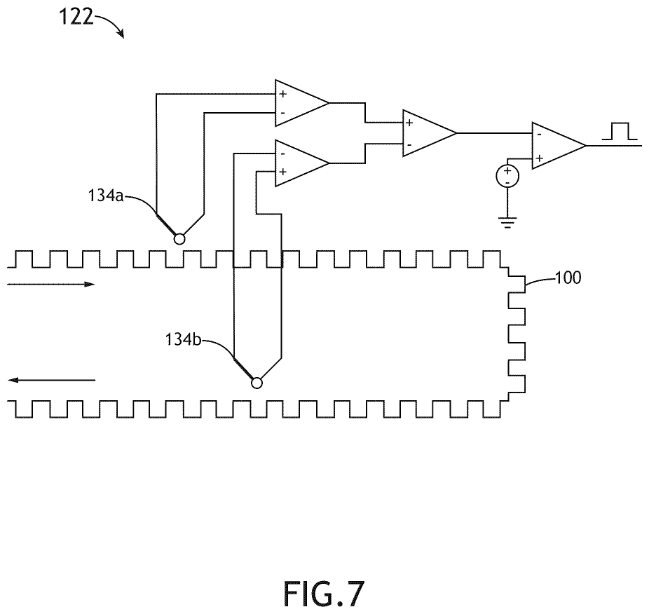

FIG. 7 illustrates a differential voltage circuit 136 for measuring and comparing the temperatures obtained from each side of the probe heater 100. In embodiments, the temperatures sensors 134a, 134b are implemented as thermocouple devices or other resistance temperature devices (RTD), thermistor, etc. Left side and right side temperatures are measured using the devices. During normal operation, the temperature detected by the left and right devices will be equal, or substantially equal, resulting in a 0 (zero) volt output (or substantially 0 (zero) voltage output) from the differential voltage circuit 136. If a low impedance path develops from the probe heater 100 to the probe case, the current flow through the right side 110a of the heater element will be decreased, resulting in a lower temperature in that section of the aerospace probe. The lower temperature results in a lower voltage output from the thermocouple device on the lower temperature side. This voltage difference between the two devices will be present at the differential voltage output and then compared against a voltage threshold. If the voltage difference due to decreased temperature measured by the left side device exceeds the voltage threshold, then the fault output of the comparator circuit 136 changes from a high voltage state to a low voltage state. In embodiments, a “HI” at the fault output may indicate normal heater operation, whereas a “LO” at the fault output may indicate degraded heater operation.

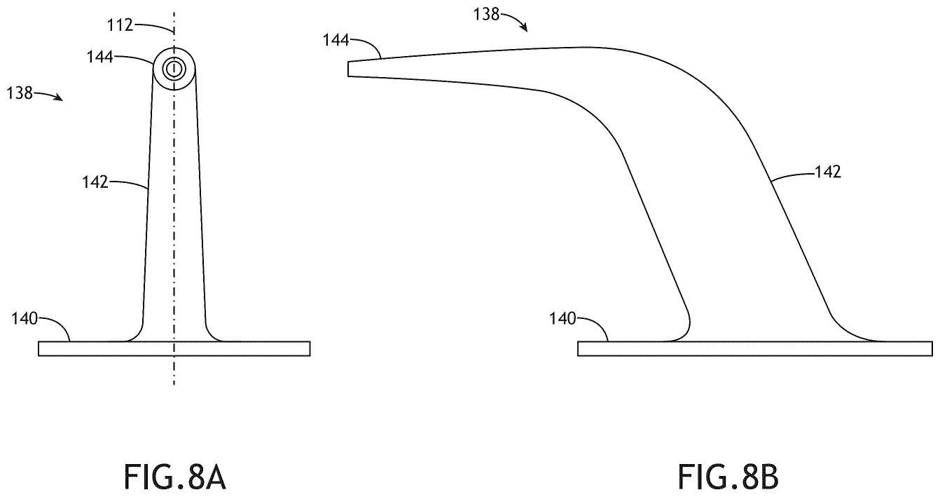

FIGS. 8A and 8B illustrate respective front and side elevation views of a non-limiting example of an aerospace probe 138. As shown, the aerospace probe 136 includes a baseplate 140 for mounting to an aircraft, a strut 142 extending upwardly from the baseplate 140, and a sensing head 144 mounted atop the strut 142. In some embodiments, portions of the aerospace probe 138 may be integrally formed. In the case of an air data sensing probe, the strut 142 extends upwardly to position the sensing head 144 away from the aircraft and into the free airstream where the sensing head 144 collects the ambient pressures (e.g., statis or impact). As shown, the exemplary probe design is symmetric about a vertical plane of symmetry 112 through the strut 142 and sensing head 144 portions for consistent airflow.

In embodiments, probe heaters according to the present disclosure which provide deicing and anti-icing capability may also be inherently symmetric in their heat distribution in the sensing head 144 and strut 142 with each side requiring nearly identical heating. As discussed above, one of the failure modes of probe heaters is the development of an alternative path to ground that shunts current flow around the full length of the heater. By incorporating left and right side sensors (e.g., at least one of temperature and current on each side), the operating condition of the probe heater can be monitored to ensure both sides of the strut are operating at the same temperature indicating that current is flowing through the complete heater length.

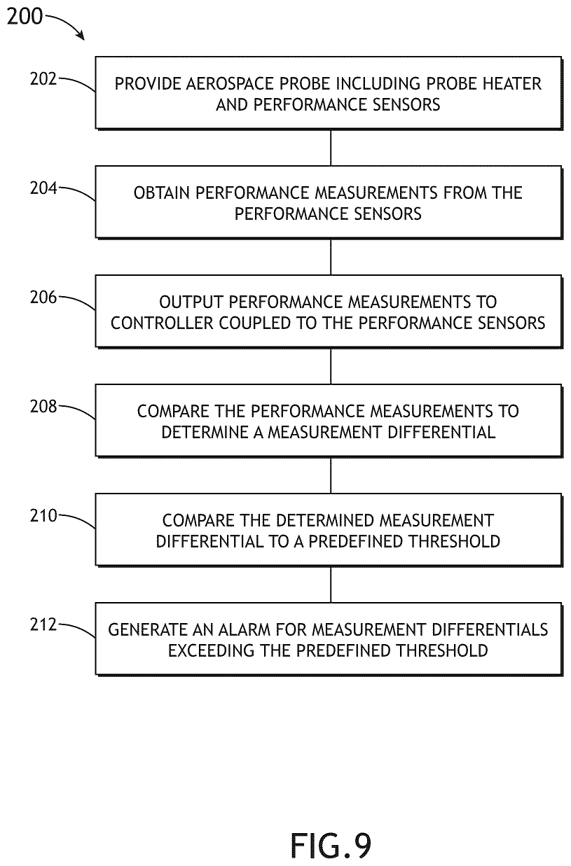

FIG. 9 illustrates a methodology 200 by which the performance of a symmetrical probe heater may be monitored to ensure sufficient deicing performance. In a step 202, an aerospace probe is provided including at least one sensor associated with a first operating side of the probe heater and at least one sensor associated with a second operating side of the probe heater. In a step 204, the at least one sensor associated with each side obtains a measurement (e.g., current, temperature, both) associated with the operation of the probe heater. For instance, in the case of current sensors, a current sensor positioned on the incoming current side obtains an incoming current measurement and a current sensor positioned on the outgoing current side obtains an outgoing current measurement, and in the case of temperature sensors, a temperature sensor positioned on one side obtains a first temperature measurement and a temperature sensor positioned on the opposing side obtains a second temperature measurement. In a step 206, the obtained measurements are output to a controller. In a step 208, the controller, for example by way of a differential voltage circuit, determines a difference between the obtained measurements from the respective sides. In a step 210, the controller, for example by way of a voltage comparator, compares the measurement difference to a predefined threshold, for example a voltage threshold, to determine if the difference exceeds the predefined threshold. Finally, in a step 212, the method concludes with the controller generating an alarm that is output to the flight crew to inform about a degraded condition of the probe that may result in a potential safety issue.

In probe embodiments including both current sensors and temperature sensors, an alarm may be generated associated with exceeding one predefined threshold (e.g., current alarm), and a further alarm may be generated associated with exceeding another predefined threshold (e.g., temperature alarm). In some embodiments, there may be a relationship between the two alarms, for example, wherein a first alarm indicates a current condition pertaining to current performance and a second alarm indicates a temperature condition pertaining to temperature performance. In some embodiments, in the case of a short circuit, a current condition may manifest sooner than a temperature difference resulting from the short circuit. In some embodiments, one or more of the alarm and the further alarm may be generated and communicated to the flight crew.

In embodiments, the controller 118 may include one or more processors and a memory device, or memory. For example, the one or more processors may be configured to execute a set of program instructions maintained in the memory device. The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In embodiments, the one or more processors may be embodied as a desktop computer, mainframe computer system, workstation, image computer, parallel processor, networked computer, or any other computer system configured to execute a program. Moreover, different subsystems of the present disclosure may include a processor or logic elements suitable for carrying out at least a portion of the steps described herein. Further, the steps described herein may be carried out by a single controller or, alternatively, multiple controllers. Further, the controller may analyze or otherwise process data received from the sensors and feed the data to additional components or external to the system.

The memory device may include any storage medium known in the art suitable for storing program instructions executable by the associated one or more processors. For example, the memory device may include a non-transitory memory medium. As an additional example, the memory device may include, but is not limited to, a read-only memory, a random-access memory, a magnetic or optical memory device (e.g., disk), a magnetic tape, a solid-state drive and the like. It is further noted that the memory device may be housed in a common controller housing with the one or more processors.

From the above description, it is clear that the inventive concepts disclosed herein are well adapted to achieve the objectives and to attain the advantages mentioned herein as well as those inherent in the inventive concepts disclosed herein. While presently preferred embodiments of the inventive concepts disclosed herein have been described for purposes of this disclosure, it will be understood that numerous changes may be made which will readily suggest themselves to those skilled in the art and which are accomplished within the broad scope and coverage of the inventive concepts disclosed and claimed herein.

What is claimed is:

1. A method for detecting a probe heater operating in a degraded condition, the method comprising:
obtaining, by an incoming current sensor coupled to a high potential side of a resistive probe heater, a measurement of incoming electrical current;
obtaining, by an outgoing current sensor coupled to a low potential side of the resistive probe heater, a measurement of outgoing electrical current;
determining, by a controller including processing circuitry, a difference in electrical current between the measurement of outgoing electrical current and the measurement of incoming electrical current;
comparing, by the controller, the difference in electrical current to a predefined electrical current threshold; and
generating an alarm, by the controller, when the difference in electrical current exceeds the predefined electrical current threshold.

2. The method according to claim 1, wherein:
the resistive probe heater is powered by a direct current (DC) power source;
the incoming current sensor and the outgoing current sensor are matched resistors;
the predefined electrical current threshold is a voltage threshold; and
the controller is configured to determine a voltage differential between the matched resistors and generate the alarm when the voltage differential exceeds the voltage threshold.

3. The method according to claim 1, wherein:
the controller is implemented as a voltage comparator circuit having a fault output configured to change from a high voltage state to a low voltage state when the voltage differential exceeds the voltage threshold;
the high voltage state corresponds to normal resistive probe heater operation; and
the low voltage state corresponds to degraded resistive probe heater operation.

4. The method according to claim 1, wherein:
the resistive probe heater is powered by an alternating current (AC) power source;
the incoming current sensor and the outgoing current sensor are implemented as at least one current transformer configured to convert the incoming electrical current to incoming voltage and the outgoing electrical current to outgoing voltage;
the predefined electrical current threshold is a voltage threshold; and
the controller is configured to determine a voltage differential between the incoming voltage and the outgoing voltage and generate the alarm when the voltage differential exceeds the voltage threshold.

5. The method according to claim 4, wherein:
the controller is implemented as a voltage comparator circuit having a fault output configured to change from a high voltage state to a low voltage state when the voltage differential exceeds the voltage threshold;
the high voltage state corresponds to normal resistive probe heater operation; and
the low voltage state corresponds to degraded resistive probe heater operation.

6. The method according to claim 1, wherein:
the resistive probe heater is disposed in an aerospace probe including a strut and a head positioned atop the strut;
the aerospace probe includes a first side and a second side symmetrical about a vertical plane of symmetry; and
the resistive probe heater is symmetrical about the vertical plane of symmetry to provide symmetric heat distribution in the first and second sides.

7. The method according to claim 1, the method further comprising:
obtaining, by a first temperature sensor disposed in a first side of the aerospace probe, a first temperature measurement;
obtaining, by a second temperature sensor disposed in a second side of the aerospace probe, a second temperature measurement;
determining, by the controller, a difference in temperature between the first temperature measurement and the second temperature measurement;
comparing, by the controller, the difference in temperature to a predefined temperature threshold; and
generating a further alarm, by the controller, when the difference in temperature exceeds the predefined temperature threshold.

8. The method according to claim 7, wherein:
the first temperature sensor is configured to output a first voltage;
the second temperature sensor is configured to output a second voltage;
the predefined temperature threshold is a voltage threshold; and
the controller is implemented as a differential voltage circuit configured to determine a differential voltage between the first and second voltages and generate the further alarm when the differential voltage exceeds the voltage threshold.

9. The method according to claim 7, wherein:
the controller is configured to generate the alarm and the further alarm separately or collaboratively; and
the controller is configured to output the alarm and the further alarm to an aircraft system configured to convey situational information to an aircraft flight crew.

10. A method for detecting a degraded condition of a probe heater disposed in an aerospace probe, the method comprising:
obtaining, by a first temperature sensor disposed in a first side of the aerospace probe, a first temperature measurement;
obtaining, by a second temperature sensor disposed in a second side of the aerospace probe, a second temperature measurement;
determining, by a controller including processing circuitry, a temperature difference between the first temperature measurement and the second temperature measurement;
comparing, by the controller, the temperature difference to a predefined temperature threshold; and
generating an alarm, by the controller, when the temperature difference exceeds the predefined temperature threshold.

11. The method according to claim 10, wherein:
the first temperature sensor is configured to output a first voltage;
the second temperature sensor is configured to output a second voltage;
the predefined threshold is a voltage threshold; and
the controller is implemented as a differential voltage circuit configured to determine a differential voltage between the first and second voltages and generate the alarm when the differential voltage exceeds the voltage threshold.

12. The method according to claim 10, wherein:
the aerospace probe includes a strut and a head positioned atop the strut;
the first and second sides of the aerospace probe are symmetrical about a vertical plane of symmetry;
the probe heater is symmetrical about the vertical plane of symmetry to provide symmetric heat distribution in the first and second sides; and
the first and second temperature sensors are symmetrically positioned about the vertical plane of symmetry.

13. The method according to claim 10, the method further comprising:
obtaining, by an incoming current sensor coupled to a high potential side of the probe heater, a measurement of incoming electrical current;
obtaining, by an outgoing current sensor coupled to a low potential side of the probe heater, a measurement of outgoing electrical current;
determining, by the controller, a difference in electrical current between the measurement of outgoing electrical current and the measurement of incoming electrical current;
comparing, by the controller, the difference in electrical current to a predefined electrical current threshold; and
generating a further alarm, by the controller, when the difference in electrical current exceeds the predefined electrical current threshold.

14. The method according to claim 13, wherein:
the probe heater is a resistive heating element powered by a direct current (DC) power source;
the incoming current sensor and the outgoing current sensor are matched resistors;
the predefined electrical current threshold is a voltage threshold; and
the controller is configured determine a voltage differential between the matched resistors and generate the further alarm when the voltage differential exceeds the voltage threshold.

15. The method according to claim 13, wherein:
the probe heater is a resistive heating element powered by an alternating current (AC) power source;
the incoming current sensor and the outgoing current sensor are implemented as at least one current transformer configured to convert the incoming electrical current to incoming voltage and the outgoing electrical current to outgoing voltage;
the predefined electrical current threshold is a voltage threshold; and
the controller is configured determine a voltage differential between the incoming voltage and the outgoing voltage and generate the further alarm when the voltage differential exceeds the voltage threshold.

16. The method according to claim 13, wherein:
the controller is configured to generate the alarm and the further alarm separately or collaboratively; and
the controller is configured to output the alarm and the further alarm to an aircraft system configured to convey situational information to an aircraft flight crew.

17. An aerospace probe assembly, comprising:
a probe casing;
a resistive prove heater disposed in the probe casing;
an incoming current sensor coupled to a high potential side of the resistive probe heater;
an outgoing current sensor coupled to a low potential side of the resistive probe heater; and
a controller, including processing circuitry, configured to:
obtain, from the incoming current sensor, a measurement of incoming electrical current;
obtain, from the outgoing current sensor, a measurement of outgoing electrical current;
determine a difference in electrical current between the measurement of outgoing electrical current and the measurement of incoming electrical current;
compare the difference in electrical current to a predefined electrical current threshold; and
generate an alarm when the difference in electrical current exceeds the predefined electrical current threshold.

18. The aerospace probe assembly according to claim 17, wherein the controller is further configured to output the alarm to an aircraft system configured to convey a degraded operating condition of the resistive probe heater to an aircraft flight crew.

19. The aerospace probe assembly according to claim 17, wherein the probe casing includes a first side and a second side that are continuously formed and symmetrical about a vertical plane of symmetry;
the aerospace probe assembly further comprises:
a first temperature sensor disposed in the first side of the aerospace probe and communicatively coupled to the controller; and
a second temperature sensor disposed in a second side of the aerospace probe and communicatively coupled to the controller; and
wherein the controller is further configured to:
obtain from the first temperature sensor a first temperature measurement;
obtain from the second temperature sensor a second temperature measurement;
determine a difference in temperature between the first temperature measurement and the second temperature measurement;
compare the difference in temperature to a predefined temperature threshold; and
generate a further alarm when the difference in temperature exceeds the predefined temperature threshold.

20. The aerospace probe assembly according to claim 19, wherein the controller is further configured to output the further alarm to the aircraft system separately from or collaboratively with the output of the alarm to the aircraft system.
